(19) United States
(12) Patent Application Publication
(10) Pub. No.: US 2019/0040522 A1
(43) Pub. Date: Feb. 7, 2019

(54) ABSORPTION SHIELDING DEVICE AND EVAPORATION DEVICE HAVING THE SAME

(71) Applicant: BOE TECHNOLOGY GROUP CO., LTD., Beijing (CN)

(72) Inventor: Chengyuan LUO, Beijing (CN)

(21) Appl. No.: 15/950,334

(22) Filed: Apr. 11, 2018

(30) Foreign Application Priority Data
Aug. 4, 2017 (CN) 201710661318.8

(51) Int. Cl. C23C 14/24; B01D 53/02; C23C 14/12

(52) U.S. Cl. CPC C23C 14/24; B01D 53/02; H01L 51/56; B01D 2253/202; B01D 2257/70; C23C 14/12

(57) ABSTRACT

An absorption shielding device includes a case, a plurality of flipped sheets and a linkage mechanism. The case has an opening on one face. The plurality of flipped sheets are arranged parallel to one another in the opening, and an absorption film being provided on the front face. The linkage mechanism is provided in the case and connected to each of the flipped sheets, to drive synchronous movement of the flipped sheets, such that the absorption shielding device is switched between an absorbing state and a shielding state. In the absorbing state, the front surface of each flipped sheets faces outwardly and closes the opening, and in the shielding state, the back surface of each flipped sheets faces outwardly and closes the opening.

### CROSS REFERENCE

This application is based upon and claims priority to Chinese Patent Application No. 201710661318.8, filed on Aug. 4, 2017, the entire contents thereof are incorporated herein by reference.

### TECHNICAL FIELD

The present disclosure relates to a technical field of an evaporation equipment, particularly, to an absorption shielding device and an evaporation equipment having the absorption shielding device.

### BACKGROUND

In an evaporation process of organic materials, the organic materials are deposited on the wall of an evaporation chamber. During evacuation and inflation of air, the organic material powders deposited on the wall will be suspended again to form foreign particles, and thereby affecting performance of the device. The traditional way is to add a shielding plate with a coating layer, which needs to be replaced for a certain period, but it still cannot prevent the deposited material powders from soaring effectively.

### SUMMARY

An absorption shielding device according to one aspect of the present disclosure, includes a case, a plurality of flipped sheets and a linkage mechanism. The case has an opening on one face. The plurality of flipped sheets are arranged parallel to one another in the opening, and an absorption film being provided on the front face. The linkage mechanism is provided in the case and connected to each of the flipped sheets, to drive synchronous movement of the flipped sheets, such that the absorption shielding device is switched between an absorbing state and a shielding state. In the absorbing state, the front surface of each flipped sheets faces outwardly and closes the opening, and in the shielding state, the back surface of each flipped sheets faces outwardly and closes the opening.

According to one embodiment of the present disclosure, the linkage mechanism includes two gear racks, a plurality of gears and a drive assembly. The two gear racks are provided parallel to and spaced from each other in the opening. A plurality of gears are provided in pairs on both sides of the plurality of the flipped sheet, and every pair of the gears are engaged with the two gear racks, respectively. The drive assembly is connected to the gear rack to drive movement of the gear rack, such that the gear rack drive synchronous flipping of the flipped sheets.

According to one embodiment of the present disclosure, the drive assembly includes a memory alloy spring sheet and a heating device. The memory alloy spring sheet is connected between the case and one end portion of the gear rack. The heating device is used for heating the memory alloy spring sheet. Wherein, the heating device may heat the memory alloy spring sheet to be prolonged, when the heating device stops working, the memory alloy spring sheet returns to an original length, and the memory alloy spring sheet drives movement of the gear rack through expansion and contraction.

According to one embodiment of the present disclosure, a maximum stretched length of the memory alloy spring sheet is equal to half of a perimeter of the gear.

According to one embodiment of the present disclosure, the drive assembly includes at least two memory alloy spring sheets respectively connected to two gear racks, the heating device simultaneously heats two memory alloy spring sheets, such that temperatures of the two memory alloy spring sheets change synchronously, and thereby the two gear racks move synchronously.

According to one embodiment of the present disclosure, the memory alloy spring sheet has a sheet-shaped structure or a spiral structure, and/or the memory alloy spring sheet is a copper-zinc-aluminum alloy.

According to one embodiment of the present disclosure, a surface of the absorption film facing to the flipped sheet is a Gecko chorionic bionic film, and/or a surface of the absorption film facing away from the flipped sheet is a PI chorionic film.

According to one embodiment of the present disclosure, the absorption shielding device is in an absorbing state and in a shielding state, the adjacent flipped sheets are partially overlapped.

According to the other aspect of the present disclosure, there is provided with an evaporation equipment, including an evaporation chamber. The absorption shielding device according to the aforesaid embodiments is provided in the evaporation chamber. Wherein the absorption shielding device is switched to be in the absorbing state, when the evaporation equipment initiates the evaporation operation; and the absorption shielding device is switched to be a closing state, when the evaporation equipment accomplishes the evaporation operation.

According to one embodiment of the present disclosure, the case of the absorption shielding device is formed by a recess on a wall of the evaporation chamber.

### BRIEF DESCRIPTION OF THE DRAWINGS

The various objects, features and advantages of the present disclosure will be apparent from the following detailed description of the preferable embodiments taken in conjunction with the accompanying drawings. The figures of the present disclosure are only illustrative, but not necessarily to scale. In the drawings, the same reference numbers will be used throughout the drawings to refer to the same or like parts. In which,

FIG. 1 is a front view of an absorption shielding device according to one exemplary embodiment;

FIG. 2 is a sectional view along line A-A of FIG. 1;

FIG. 3 is a perspective view of one flipped sheet of the absorption shielding device as shown in FIG. 1.

### DETAILED DESCRIPTION

Typical embodiments embodying features and advantages of this disclosure will be set forth in detail. It should be understood that various modifications may be made on different embodiments of this disclosure without departing from the scope of this disclosure, wherein the description and drawings in essential are used for description but not limit to this disclosure.

Hereinafter, various exemplary embodiments of the present disclosure will be described with reference to the drawings constituting a part of the present disclosure, in which different exemplary structures, systems and steps of various aspects of the present disclosure may be realized in an exemplary example. It should be understood that other specific technical solutions of the components, structures, exemplary devices, systems, and steps may be used and may be structurally and functionally modified without departing from the scope of the present disclosure. Moreover, although the terms “upper end”, “lower end”, “between”, “side” etc. may be used in this specification to describe different exemplary features and elements of the present disclosure, these terms are used herein only for convenience, for example, the exemplary direction as described according to the drawings. It should not be understood from any content of the specification that particular three-dimensional direction requiring a structure falls within the scope of the present disclosure.

### Embodiment of the Absorption Shielding Device

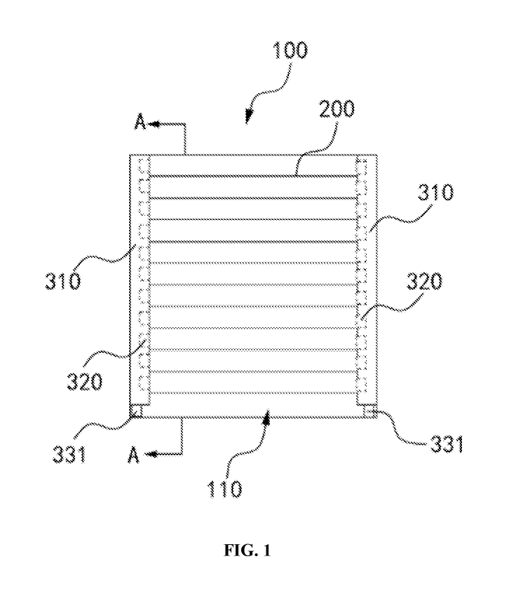

Referring to FIG. 1, FIG. 1 representatively shows a front view of the absorption shielding device that may embody a principle of the present disclosure. In this exemplary embodiment, as an example, the absorption shielding device as proposed in the present disclosure is used in the evaporation equipment, for example, for absorbing and blocking the organic material powder in the evaporation equipment. Those skilled in the art would readily appreciate that many modifications, additions, substitutions, deletions, and other changes may be made to the specific embodiments, and such changes are contemplated by the principles of this disclosure, in order to use the absorption shielding device in the other devices or for absorbing and blocking the other substances.

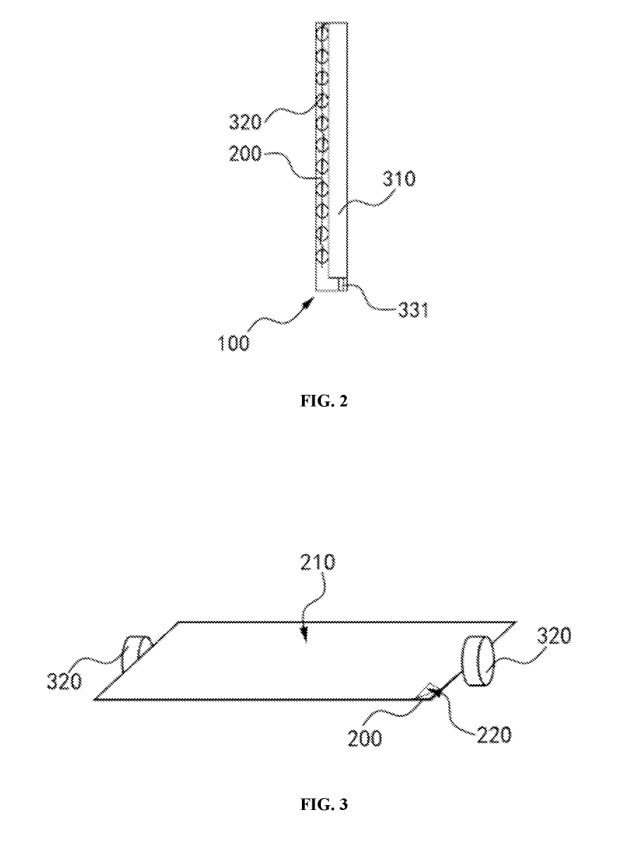

As shown in FIG. 1, in the present embodiment, the absorption shielding device as mentioned in the present disclosure mainly includes a case 100, a plurality of flipped sheets 200, and a linkage mechanism. Referring to FIG. 2 and FIG. 3, FIG. 2 representatively shows a side view of an absorption shielding device, and FIG. 3 representatively shows a three-dimensional structural view of one flipped sheet 200 (including gears 320 on both sides of the flipped sheet 200) of the absorption shielding device. Hereinafter, the structure, connection mode and functional relationship of the main components of the absorption shielding device as mentioned in the present disclosure will be described in detail in conjunction with the above drawings.

As shown in FIG. 1, in the present embodiment, the case 100 has an opening 110 on one surface thereof. Wherein, in the present embodiment, the opening 110 completely covers entire location of the surface of the case 100, that is, the surface of the case 100 has an open structure. Accordingly, as an example of the case 100 having substantially rectangular surface as shown in FIG. 1, the shape of the opening 110 is substantially rectangular.

In other embodiments, the surface of the case 100 may also be designed in other shapes, that is, the opening 110 may correspondingly have the other shapes. Furthermore, the shape of the opening shape is not limited to be identical to the shape of the surface of the case 100, and the size of the opening 110 may also be smaller than the size of the surface of the case 100, which all are not limited thereto.

As shown in FIG. 1, in the present embodiment, a plurality of flipped sheets 200 are arranged parallel to each other at the opening 110, and each of the flipped sheets 200 is provided with an adsorption film on the front surface. Specifically, in the present embodiment, one surface of the absorption film facing to the flipped sheet 200 (i.e., an attachment surface of the absorption film to the slipped sheet 200) preferably adopts a Gecko chorionic bionic film 220, which may be absorbed onto the flipped sheet 200 in a vacuum environment and may be replaced conveniently. In addition, the other surface of the absorption film facing away from the flipped sheet 200 (i.e., an adsorption surface exposed to the external environment) preferably adopts a PI chorionic film 210 (based on polyimide film), which may absorb substances such as organic material powders. In addition, PI chorionic film 210 has excellent heat-and-cold temperature resistance, electrical insulation, cohesiveness, radiation resistance, chemical resistance, and thereby may be used under a low-temperature environment of −269° C.-280° C. for a long term, and may be used under a high-temperature environment of 400° C. for a short term.

In other embodiments, the materials of the front and back surfaces of the flipped sheet 200 are not limited to the film types as above-described in the present embodiment, and the two films in this embodiment are not limited to being used together.

As an example, in the present embodiment, a villus of the PI chorionic film 210 may have a diameter preferably from 50 μm to 1000 μm, the length preferably from 0.1 mm to 1 mm, but not limited thereto.

For example, in the present embodiment, when the absorption shielding device is in an absorbing state and in a shielding state, every two adjacent flipped sheets 200 are partially overlapped. That is, as an example, a rotational axis of the flipped sheet 200 being inverted relative to a housing coincides with a central line of the flipped sheet 200 (i.e., the gears 320 are arranged at the central position on one surface of the flipped sheet 200), a width of the flipped sheet 200 (i.e., a size in the other direction perpendicular to the central line direction) is slightly larger than the distance between the central lines of the adjacent flipped sheets 200 (i.e., a distance between the adjacent flipped sheets 200). Thereby, it is possible to eliminate a gap between the adjacent flipped sheets 200 when the absorption shielding device is in the shielding state (and also including the absorbing state), and further reduce soaring phenomenon of the organic material powder.

In the present embodiment, the linkage mechanism is provided in the case 100 and connected to the individual flipped sheet 200 to drive the individual flipped sheet 200 to be flipped synchronously, so that the absorption shielding device may be switched between the absorbing state and the shielding state. Wherein, the linkage mechanism drives the front surface of the flipped sheet 200 to surface the outside, and close the opening 110, when he absorption shielding device is in the absorbing state. That is, PI chorionic film 210 on each of the flapped sheets 200 is exposed outwardly with respect to case 100 to absorb substances such as organic material powder in the external environment. The linkage mechanism drives the back surface of the flipped sheet 200 to surface outside, and close the opening 110, when the absorption shielding device is in the shielding state. That is, the PI chorionic film 210 on each of the flipped sheets 200 faces toward an inner cavity of the case 100 to prevent the organic material powder that has been absorbed by the PI chorionic film 210 from being scattered into the external environment again and thereby generating a phenomenon of the powder soaring, so as to avoid occurrence of secondary pollution.

Specifically, as shown in FIG. 1 to FIG. 3, in the present embodiment, the linkage mechanism mainly includes two gear racks 310, a plurality of gears 320 and a drive assembly. Specifically, two gear racks 310 are provided in parallel to each other, and spaced from each other. A plurality of gears 320 are in pairs provided on both sides of the plurality of the flipped sheets 200, respectively. Each pair of gears 320 mesh with two gear racks 310, respectively. The driving assembly is connected to the gear rack 310 to driving the gear rack 310 to move, such that the gear rack 310 may drive each flipped sheet 200 to be flipped synchronously. As above described, the linkage mechanism is formed by using the gear racks 310 and the gears 320 that cooperate with each other, so that synchronous turnover of the plurality of the flipped sheets 200 may be realized, and the structure is simple and easy to be arranged and maintained.

In other embodiments, based on a design for cooperating the gear rack 310 with the gear 320, the number of the gear rack 310 may also be one, and the gear rack 310 may be provided on one surface of the plurality of the flipped sheets 200. Correspondingly, the plurality of gears 320 may be arranged on one surface of the plurality of flipped sheets 200 corresponding to the gear rack 310, respectively. Namely, a function of driving the flipped sheets 200 to turnover synchronously by moving the gear racks 310 may be achieved by engagement of the gear racks 310 with the gears 320 on the same side of the flipped sheets 200. Herein, the other side of each flipped sheet 200 on which no gear 320 is provided may rotatably (for example, by means of a shaft) connected to the housing, but not limited thereto.

As an example, based on a design of the gear rack 310 and the gear 320, a position of the opening 110 of the case 100 corresponding to the gear 320 cannot be shielded by the flipped sheet 200. In the present embodiment, the case 100 may remain a part of structure on both sides of the opening 110 of the case 100 for covering two columns of the gears 320. That is to say, the two columns of the gears 320 as well as the gear racks 310 are not exposed to the opening 110, and the size and the shape of the opening 110 may be identical to the size and the shape of the folded flipped sheets 200 while the flipped sheets 200 are synchronously turned to the front or back surface, which thereby may basically eliminate the soaring phenomenon of the organic material powder when the absorption shielding device is in the shielding state.

As shown in FIG. 1 and FIG. 2, in the present embodiment, the drive assembly mainly includes a memory alloy spring sheet 331 and a heating device. Specifically, the memory alloy spring sheet 331 is connected between the case 100 and one end portion of the gear rack 310. The heating device is used to heat the memory alloy spring sheet 331. As above described, due to a characteristic of the memory alloy spring sheet 331 that is thermally deformed (i.e., the memory alloy spring sheet 331 returns to a high-temperature phase shape when being heated, and returns to a low-temperature phase shape when being cooled), the memory alloy spring sheet 331 prolongs to a preset working length from an original length when the heating device heats the memory alloy spring sheet 331, and the memory alloy spring sheet 331 cools down and returns to its original length when the heating device stops working. Accordingly, expansion and contraction of the memory alloy spring sheet 331 may be controlled by the heating device to drive movement of the gear rack 310, such that synchronous turnover of the plurality of flipped sheets 200 may be achieved. In the present embodiment, the memory alloy spring sheet 331 may be preferably two, and are respectively connected between the ends of two gear racks 310 and the case 100. In addition, the heating device may be one or two respectively corresponding to two memory alloy spring sheets 331, and thermal uniformity of the two memory alloy spring sheets 331 should be taken into account previously.

In other embodiments, when only one gear rack 310 is provided, based on such design of the memory alloy spring sheet 331 and the heating device, only one memory alloy spring sheet 331 needs to be provided, accordingly. In addition, the drive assembly also may adopt other device or assemblies to drive the movement of the gear rack 310, but not limited to the design as illustrated in the present embodiment.

For example, in the present embodiment, the maximum stretched length of the memory alloy spring sheet 331 (i.e., a length difference between the preset working length and the original length) is equal to half of a perimeter of the gear 320. Accordingly, a movement distance of the gear rack 310 caused based on the memory alloy spring sheet 331 is thermally extended is equal to half of the perimeter of the gear 320, that is, after the memory alloy spring sheet 331 is thermally extended to the maximum length (i.e., the preset working length), the gear 320 is rotated by the gear rack 310 for a half circle, and the front surface of the flipped sheet 200 just faces to outside with respect to the case 100, and vice versa.

The drive assembly includes two memory alloy spring sheets 331 respectively connected to two gear racks 310. The heating device simultaneously heats two memory alloy spring sheets 331 (it is also possible to heat two memory alloy spring sheets 331 by using two heating devices respectively) such that temperatures of the two memory alloy spring sheet 331 change synchronously, and thereby the two gear racks 310 move synchronously. When the memory alloy spring sheet 331 and the heating device constitute the drive assembly, a function of driving the gear rack 310 movable may be realized by using the characteristics of the thermal deformation of the memory alloy spring sheet 331 and heating of the heating device.

For example, as shown in FIG. 1 and FIG. 2, in the present embodiment, the memory alloy spring sheet 331 may preferably be a sheet-shaped structure. In other embodiments, the memory alloy spring sheet 331 may also be selected from other structures such as a spiral structure (i.e., a memory alloy spring).

For example, in the present embodiment, the material of the memory alloy spring sheet 331 may preferably be a copper-zinc-aluminum alloy, i.e., Cu—Zn—Al, having a temperature variation in a range of 65° C.-85° C. which is a temperature range to be easily reachable. In other embodiments, the material of the memory alloy spring sheet 331 may also be selected from other types of alloys, and the specific material may be flexibly selected according to the temperature variations as desired, for example Fe—Pt, Ti—Ni, Ti—Ni—Pd, Ti—Nb, U—Nb, Fe—Mn—Si, Au—Cd, Ag—Cd, Cu—Zn, Cu—Zn—Sn, Cu—Zn—Al, Cu—Zn—Si, Cu—Sn, Cu—Zn—Ga, In—Ti, Au—Cu—Zn and NiAl, etc., in a temperature range of substantially 50° C.-600° C.

For example, in the present embodiment, the heating device is controlled by the controller (the heating device may be connected to the controller). The controller may be integrated in the control system of an evaporation equipment, and may be controlled through the external operation interface of the control system to control the heating device. In other embodiments, a separate external operating interface may also be provided to control the heating device, but not limited thereto.

As above described, the absorption shielding device as proposed in the present disclosure may be switched between the absorbing state and the shielding state by means of such design that the linkage mechanism drives a plurality of flipped sheets to synchronously flip. In the absorbing state, each flipped sheet has its front surface facing outside and closing the opening of the case, to absorb the organic material powder by using the absorption film on the front surface of the flipped sheet. In the shielding state, each flipped sheet has its back surface facing outside and closing the opening of the case, to block the organic material powder absorbed in the absorbing state within the case, so as to avoid the soaring of the organic material powder.

Herein, it should be noted that the absorption shielding device as shown in the drawings and as described in the specification is just one example of several absorption shielding device that may employ a principle of the present disclosure. It should be clearly understood that the principle of the present disclosure is absolutely not only limited to any detail of the absorption shielding device as shown in the drawings or as described in the specification or any component of the absorption shielding device.

### Embodiment of the Evaporation Equipment

In the present embodiment, as an example, the evaporation equipment as proposed by the present disclosure is used in an OLED light-emitting layer manufacturing process. Those skilled in the art would readily appreciate that many modifications, additions, substitutions, deletions, and other changes may be made to the specific embodiments, and such changes are contemplated by the principles of this disclosure, in order to use the evaporation equipment in the other manufacturing processes or field.

In the present embodiment, the evaporation equipment as proposed by the present disclosure mainly includes an evaporation chamber and an absorption shielding device. Specifically, absorption shielding device as proposed by the present disclosure is provided within the evaporation chamber. Thereby, the absorption shielding device is switched to be in the absorbing state to absorb the organic material powder generated in an evaporation operation, when the evaporation equipment initiates the evaporation operation. The absorption shielding device is switched to be in the closed state to block the organic material powder absorbed in the evaporation operation within an internal chamber of the case, when the evaporation equipment accomplishes the evaporation operation, so as to avoid occurrence of a phenomenon of soaring the organic material powder while the evaporation equipment performs other processes.

For example, in the present embodiment, the case of the absorption shielding device may preferably be formed by a recess on the wall of the evaporation chamber. Thereby, a plurality of flipped sheets, the linkage mechanism and the drive assembly of the absorption shielding device are provided in the recess structure formed by the wall of the evaporation chamber. In the other embodiments, the absorption shielding device may also be configured to be separated from the evaporation chamber or the case in the other using environment, and the case is mounted to the wall of the evaporation chamber.

In addition, in the present embodiment, the absorption shielding device is located in several selectable positions such as a sidewall and a top of the evaporation chamber. For choosing the position within the evaporation chamber where the absorption shielding device is provided, factors such as the absorption shielding device being not interfered with other structures of the evaporation equipment to achieve a better adsorption effect may be comprehensively considered.

As above described, the evaporation equipment as proposed by the present disclosure, by means of providing the absorption shielding device in the evaporation chamber of the evaporation equipment, may absorb the organic material powder generated during the evaporation operation by using the absorption shielding device when the evaporation equipment initiates the evaporation operation, and may block the absorbed organic material powder within the case by using the absorption shielding device when the evaporation equipment accomplishes the evaporation operation, so as to avoid the organic material power from soaring in the other processes of the evaporation equipment to cause secondary pollution.

For example, in one embodiment of the present disclosure, the linkage mechanism is composed of the gear rack and the gear which are cooperated with each other, which may simultaneous flipping of the plurality of the flipped sheets, and its structure is simple to be easily arranged and maintained.

For example, in one embodiment of the present disclosure, a drive assembly that is composed of the memory alloy spring sheet and the heating device may achieve a function of driving movement of the gear rack by using the characteristics of the thermal deformation of the memory alloy spring sheet and the heating of the heating device.

Herein, it should be noted that the evaporation equipment as shown in the drawings and as described in the specification is just one example of several evaporation equipment s that may employ a principle of the present disclosure. It should be clearly understood that the principle of the present disclosure is absolutely not only limited to any detail of the evacuation device as shown in the drawings or as described in the specification or any components of the evaporation equipment.

Exemplary embodiments of the absorption shielding device and the evaporation equipment having the absorption shielding device as proposed by the present disclosure are described and/or illustrated in detail. However, the embodiments of the present disclosure are not limited to the specific embodiments as described herein. Rather, the constituents and/or steps of each embodiment may be used independently and separately from the other constituents and/or steps as described herein. Each constituent and/or step of one embodiment may also be used in combination with other constituents and/or steps of the other embodiments. When elements/constituents as described and/or illustrated herein are introduced, the terms “a”, “an” and “said” when describing element/constituent/or the like as described and/or shown herein, are used to express the presence of one or more the element/constitute/or the like. The terms “include”, “comprise” and “have”, as used herein, are intended to be inclusive, and mean there may be additional elements/constituents/ or the like other than the listed elements/constituents/or the like.

Although the absorption shielding device and the evaporation equipment having the absorption shielding device as proposed by the present disclosure are disclosed according to different particular embodiments, those skilled in the art would recognize that the embodiments of present disclosure may be modified within the spirit and scope of the claims.

What is claimed is:

1. An absorption shielding device, comprising:
a case having an opening in one face;
a plurality of flipped sheets arranged parallel to one another in the opening, each of the flipped sheets having two side faces opposite to each other and a front surface and a back surface opposite to each other, and an absorption film being provided on the front face; and
a linkage mechanism provided in the case and connected to each of the flipped sheets, to drive synchronous movement of the flipped sheets, such that the absorption shielding device is switched between an absorbing state and a shielding state;
in the absorbing state, the front surface of each flipped sheets faces outwardly and closes the opening, and in the shielding state, the back surface of each flipped sheets faces outwardly and closes the opening.

2. The absorption shielding device according to claim 1, wherein the linkage mechanism comprises:
two gear racks provided parallel to and spaced from each other in the opening;
a plurality of gears provided in pairs on both sides of the plurality of the flipped sheet, every pair of the gears are engaged with the two gear racks, respectively; and
a drive assembly connected to the gear rack to drive movement of the gear rack, such that the gear racks drive synchronous flipping of the flipped sheets.

3. The absorption shielding device according to claim 2, wherein the drive assembly comprises:
a memory alloy spring sheet connected between the case and one end portion of the gear rack; and
a heating device for heating the memory alloy spring sheet;
wherein, the heating device selectively heats the memory alloy spring sheet to be prolonged, when the heating device stops working, the memory alloy spring sheet returns to an original length, and the memory alloy spring sheet drives movement of the gear rack through expansion and contraction.

4. The absorption shielding device according to claim 3, wherein a maximum stretched length of the memory alloy spring sheet is equal to half of a perimeter of the gear.

5. The absorption shielding device according to claim 3, wherein the drive assembly comprises at least two memory alloy spring sheets respectively connected to two gear racks respectively, the heating device simultaneously heats two memory alloy spring sheets, such that temperatures of the two memory alloy spring sheets change synchronously, and thereby the two gear racks move synchronously.

6. The absorption shielding device according to claim 3, wherein the memory alloy spring sheet has a sheet-shaped structure or a spiral structure.

7. The absorption shielding device according to claim 3, wherein a material of the memory alloy spring sheet is a copper-zinc-aluminum alloy.

8. The absorption shielding device according to claim 1, wherein a surface of the absorption film facing to the flipped sheet is a Gecko chorionic bionic film.

9. The absorption shielding device according to claim 1, wherein a surface of the absorption film facing away from the flipped sheet is a PI chorionic film.

10. The absorption shielding device according to claim 1, wherein the adjacent flipped sheets are partially overlapped when the absorption shielding device is in an absorbing state and in a shielding state.

11. An evaporation equipment, comprising
an evaporation chamber; and
an absorption shielding device, comprising:
a case having an opening in one face;
a plurality of flipped sheets arranged parallel to one another in the opening, each of the flipped sheets having two side faces opposite to each other and a front surface and a back surface opposite to each other, and an absorption film being provided on the front face; and
a linkage mechanism provided in the case and connected to each of the flipped sheets, to drive synchronous movement of the flipped sheets, such that the absorption shielding device is switched between an absorbing state and a shielding state;
in the absorbing state, the front surface of each flipped sheets faces outwardly and closes the opening, and in the shielding state, the back surface of each flipped sheets faces outwardly and closes the opening,
wherein the absorption shielding device is switched to be in the absorbing state, when the evaporation equipment initiates the evaporation operation; and the absorption shielding device is switched to be a closing state, when the evaporation equipment accomplishes the evaporation operation.

12. The evaporation equipment according to claim 11, wherein the case of the absorption shielding device is a recess formed in a wall of the evaporation chamber.

13. The evaporation equipment according to claim 11, wherein the linkage mechanism comprises:
two gear racks provided parallel to and spaced from each other in the opening;
a plurality of gears provided in pairs on both sides of the plurality of the flipped sheet, every pair of the gears are engaged with the two gear racks, respectively; and
a drive assembly connected to the gear rack to drive movement of the gear rack, such that the gear racks drive synchronous flipping of the flipped sheets.

14. The evaporation equipment according to claim 13, wherein the drive assembly comprises:
a memory alloy spring sheet connected between the case and one end portion of the gear rack; and
a heating device for heating the memory alloy spring sheet;
wherein, the heating device selectively heats the memory alloy spring sheet to be prolonged, when the heating device stops working, the memory alloy spring sheet returns to an original length, and the memory alloy spring sheet drives movement of the gear rack through expansion and contraction.

15. The evaporation equipment according to claim 14, wherein a maximum stretched length of the memory alloy spring sheet is equal to half of a perimeter of the gear.

16. The evaporation equipment according to claim 14, wherein the drive assembly comprises at least two memory alloy spring sheets respectively connected to two gear racks respectively, the heating device simultaneously heats two memory alloy spring sheets, such that temperatures of the two memory alloy spring sheets change synchronously, and thereby the two gear racks move synchronously.

17. The evaporation equipment according to claim 14, wherein the memory alloy spring sheet has a sheet-shaped structure or a spiral structure.

18. The evaporation equipment according to claim 11, wherein a surface of the absorption film facing to the flipped sheet is a Gecko chorionic bionic film.

19. The absorption shielding device according to claim 11, wherein a surface of the absorption film facing away from the flipped sheet is a PI chorionic film.

20. The evaporation equipment according to claim 11, wherein the evaporation equipment is in an absorbing state and in a shielding state, and the adjacent flipped sheets are partially overlapped.
